(19) United States
(12) Patent Application Publication
(10) Pub. No.: US 2024/0282273 A1
(43) Pub. Date: Aug. 22, 2024

(54) CONTROL METHOD OF DISPLAY DEVICE

(71) Applicants: MICRO-STAR INT’L CO.,LTD., New Taipei City (TW); MSI COMPUTER (SHENZHEN) CO.,LTD., Shenzhen City (CN)

(72) Inventors: Chun-Te YEH, New Taipei City (TW); Chung-Wen CHEN, New Taipei City (TW); Chia-Liang HOU, New Taipei City (TW)

(73) Assignees: MICRO-STAR INT’L CO.,LTD., New Taipei City (TW); MSI COMPUTER (SHENZHEN) CO.,LTD., Shenzhen City (CN)

(21) Appl. No.: 18/420,493

(22) Filed: Jan. 23, 2024

Related U.S. Application Data
(62) Division of application No. 18/129,031, filed on Mar. 30, 2023.

(30) Foreign Application Priority Data
Feb. 22, 2023 (TW) 112201572

(51) Int. Cl. G09G 3/34; H10K 59/80

(52) U.S. Cl. CPC G09G 3/3413; H10K 59/879

(57) ABSTRACT

A control method of display device including obtaining an image displayed by a display device by a computing controller; dividing the image into a plurality of sub-regions by the computing controller; computing a color weight data of each of the plurality of sub-regions by the computing controller; generating a color data for at least one of the plurality of light-emitting components corresponding to each of the plurality of sub-regions based on the color weight data of each of the plurality of sub-regions by the computing controller; transferring the color data for each of the plurality of light-emitting components to the light controller by the computing controller; and controlling each of the plurality of light-emitting components to emit corresponding color of light based on the color data by the light controller.

### CROSS-REFERENCE TO RELATED APPLICATIONS

This patent application is a divisional patent application of U.S. patent application Ser. No. 18/129,031 filed on Mar. 30, 2023 and entitled “DISPLAY DEVICE AND CONTROL METHOD THEREOF”, which is a non-provisional application claims priority under 35 U.S.C. § 119(a) on Patent Application No(s). 112201572 filed in Taiwan, R.O.C. on Feb. 22, 2023, the entire contents of which are hereby incorporated by reference.

### TECHNICAL FIELD

The disclosure relates to a display device and a control method thereof, more particularly to a display device including at least one light emitting component and the control method thereof.

### BACKGROUND

In general, in some types of display device, multiple light-emitting components are installed on a housing of a display device. In this way, the light-emitting components can emit light to indicate the state of the display device to a viewer of the display device. Alternatively, the light-emitting components can emit static light to present a visual effect to the viewer.

However, since the demand for the user experience of the display device raises, the viewer is not satisfied with such monotonous function of state indication or static light. Accordingly, a display device whose light-emitting components can produce an attractive function is required to be developed.

### SUMMARY

The disclosure provides a display device whose light-emitting components provides various and attractive functions and a control method thereof.

One embodiment of this disclosure provides a control method of display including obtaining an image displayed by a display device by a computing controller; dividing the image into a plurality of sub-regions by the computing controller; computing a color weight data of each of the plurality of sub-regions by the computing controller; generating a color data for at least one of the plurality of light-emitting components corresponding to each of the plurality of sub-regions based on the color weight data of each of the plurality of sub-regions by the computing controller; transferring the color data for each of the plurality of light-emitting components to the light controller by the computing controller; and controlling each of the plurality of light-emitting components to emit corresponding color of light based on the color data by the light controller.

According to the display device disclosed by above embodiments, the light emitted by the light-emitting components is partially emitted to the outside along the normal direction of the outer peripheral surface, and partially emitted to the outside along the normal direction of the front surface. Thus, the light-emitting components not only provide state instruction functions by emitting light along the normal direction of the front surface, but also provide a function of displaying augmented images by emitting light along the normal direction of the outer peripheral surface. In this way, the light-emitting components provide various and vivid functions. Moreover, the function of displaying augmented images provides an attractive visual effect and enhance the immersion experience when movies or games are played on the display device.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a display device according to one embodiment of the disclosure;

FIG. 2 is a partially enlarged exploded view of the display device in FIG. 1;

FIG. 3 is a further enlarged view of the display device in FIG. 2;

FIG. 4 is a flow chart of a control method of the display device in FIG. 1; and

FIG. 5 is a schematic view showing an augmented mode of the display device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

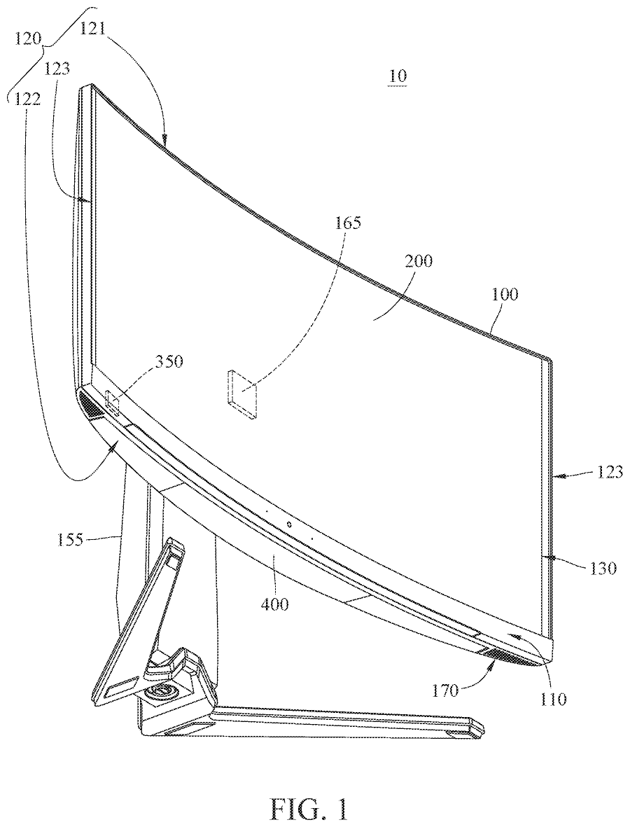

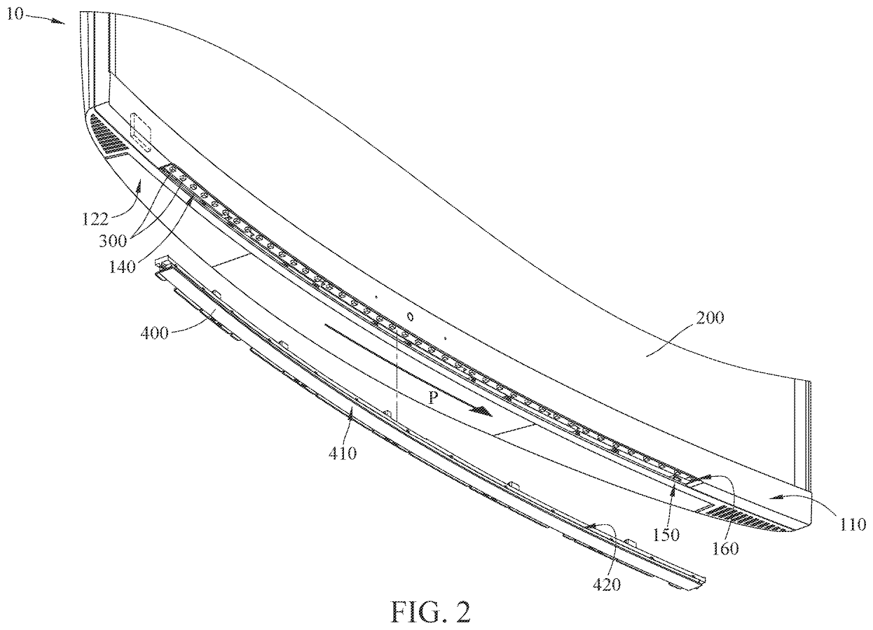

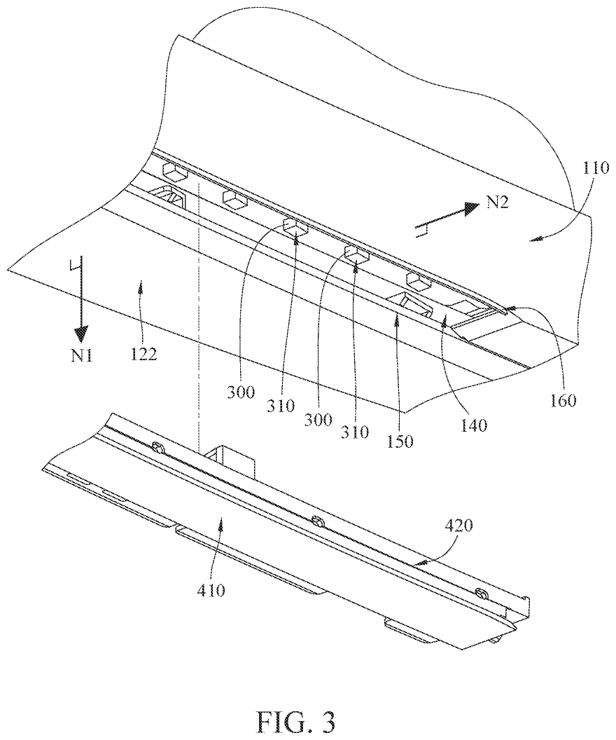

Please refer to FIGS. 1 to 3. FIG. 1 is a perspective view of a display device 10 according to one embodiment of the disclosure. FIG. 2 is a partially enlarged exploded view of the display device 10 in FIG. 1. FIG. 3 is a further enlarged view of the display device 10 in FIG. 2.

In this embodiment, the display device 10 includes a housing 100, a support base 155, a computing controller 165, a display assembly 200, a plurality of light-emitting components 300, a light controller 350 and a light-permeable component 400.

In this embodiment, the housing 100 has a front surface 110, an outer peripheral surface 120, a mounting opening 130, an accommodation recess 140, a first light exit opening 150 and a second light exit opening 160. The outer peripheral surface 120 is connected to the front surface 110. The outer peripheral surface 120 includes a top surface 121, a bottom surface 122 and two side surfaces 123. The top surface 121 faces away from the bottom surface 122. The two side surfaces 123 connect the top surface 121 and the bottom surface 122. The front surface 110 is connected to a side of each of the top surface 121, the bottom surface 122 and the two side surfaces 123. The mounting opening 130 is located on the front surface 110, and is surrounded by the outer peripheral surface 120. The accommodation recess 140 extends from the bottom surface 122 of the outer peripheral surface 120 to the front surface 110. The first light exit opening 150 is located on the bottom surface 122, and is connected to the accommodation recess 140. The second light exit opening 160 is located on the front surface 110, and is connected to the accommodation recess 140. In this embodiment, an area of the first light exit opening 150 is, for example, larger than an area of the second light exit opening 160.

In this embodiment, the support base 155 protrudes from a rear surface 170 of the housing 100 facing away from the front surface 110. In addition, the bottom surface 122 faces toward a part of the support base 155.

The computing controller 165 is disposed in the housing 100. The display assembly 200 is disposed in the mounting opening 130, and exposed to outside. The display assembly 200 is electrically connected to the computing controller 165. In this embodiment, the display assembly 200 is, for example, an organic light emitting display panel.

In this embodiment, the light-emitting components 300 are fixed to the housing 100, and located in the accommodation recess 140. Each light-emitting component 300 has a light-emitting surface 310 facing toward the first light exit opening 150. The light-emitting components 300 are arranged along, for example, a peripheral direction P of the housing 100. The light controller 350 is disposed in the housing 100, and electrically connected to the computing controller 165 and the light-emitting components 300.

The light-permeable component 400 is disposed in the accommodation recess 140, and exposed to the outside. In this embodiment, the light-permeable component 400 has a first light-permeable surface 410 and a second light-permeable surface 420 that are located adjacent to each other. The first light-permeable surface 410 is exposed to the outside from the first light exit opening 150. The second light-permeable surface 420 is exposed to the outside from the second light exit opening 160. An area of the first light-permeable surface 410 is, for example, larger than an area of the second light-permeable surface 420.

The light-emitting components 300 are configured to emit a light toward the light-permeable component 400. Further, the light emitted from the light-emitting components 300 is partially emitted to the outside from the first light exit opening 150 along a normal direction N1 of the bottom surface 122 through the first light-permeable surface 410, and partially emitted to the outside from the second light exit opening 160 along a normal direction N2 of the front surface 110 through the second light-permeable surface 420.

In this embodiment, the area of the first light exit opening 150 is larger than the area of the second light exit opening 160, the area of the first light-permeable surface 410 is larger than the area of the second light-permeable surface 420, and/or the light-emitting surfaces 310 of the light-emitting components 300 face toward the first light exit opening 150. Thus, the light emitted from the light-emitting components 300 toward a viewer of the display device 10 along the normal direction N2 of the front surface 110 is prevented from being dazzling and grainy. Note that in other embodiments, as long as the light emitted from the light-emitting components is partially emitted to the outside along the normal direction of the bottom surface and partially emitted to the outside along the normal direction of the front surface, the area of the first light exit opening may be smaller than or equal to the area of the second light exit opening, the area of the first light-permeable surface may be smaller than or equal to the area of the second light-permeable surface, and the light-emitting surface of each light-emitting component may face toward the second light exit opening.

In addition, in this embodiment, the first light-permeable surface 410 and the second light-permeable surface 420 of the light-permeable component 400 are surfaces having, for example, high haze. That is, the first light-permeable surface 410 and the second light-permeable surface 420 are hazy. Thus, the light emitted from the light-emitting components 300 is emitted to the outside of the display device 10 more uniformly. In this way, the light-emitting components 300 can produce a visual effect of bar shape.

In other embodiments, the display device may not include the light-permeable component, and the light emitted from the light-emitting components may be directly emitted toward the first light exit opening and the second light exit opening.

In this embodiment, the first light exit opening 150 is located on the bottom surface 122 of the outer peripheral surface 120, but the disclosure is not limited thereto. In other embodiments, the first light exit opening may be located on the top surface or one of the two side surfaces of the outer peripheral surface.

In addition, in other embodiments, the housing may not have the accommodation recess, and the light-emitting components may be directly disposed on the outer peripheral surface of the housing.

Note that the luminance of any one of the light-emitting components 300 according to the disclosure may be adjusted based on the usage scenario to meet actual requirements. Additionally, the visual effect produced by the light-emitting components 300 may cooperate with the on/off animation of the display device 10, and protection mechanism and real time image detection of the display assembly 200 (e.g., an organic light emitting display panel).

Note that the light-emitting components 300 according to this disclosure provide various functions. For example, the light-emitting components 300 may be configured to show the progress of the correction of the image retention (or may be referred as burn-in) of the display assembly 200 (e.g., an organic light emitting display panel). In this way, the time spending on correcting the image retention may be accurately measured. Also, the display device 10 is prevented from being accidently turned off, thereby preventing the correction of the image retention of the display assembly 200 from being interrupted. The light-emitting components 300 may emit colorful light to provide vivid visual effect. When a PC game is played on the display device 10, the light-emitting components 300 may obtain data by the connection between the USB port and the PC game via the data exchange between the light controller 350 and the computing controller 165. Thus, the light-emitting components 300 may show the information of the PC game such as remaining hit point or bullets based on the obtained data. The light-emitting components 300 may illuminate a keyboard placed on the desk supporting the display device 10. Further, a sensor may be used to cooperate with such illumination function. In detail, if the sensor detects the presence of a user in front of the display device 10, the light controller 350 and the computing controller 165 will control the light-emitting components 300 to provide such illumination function.

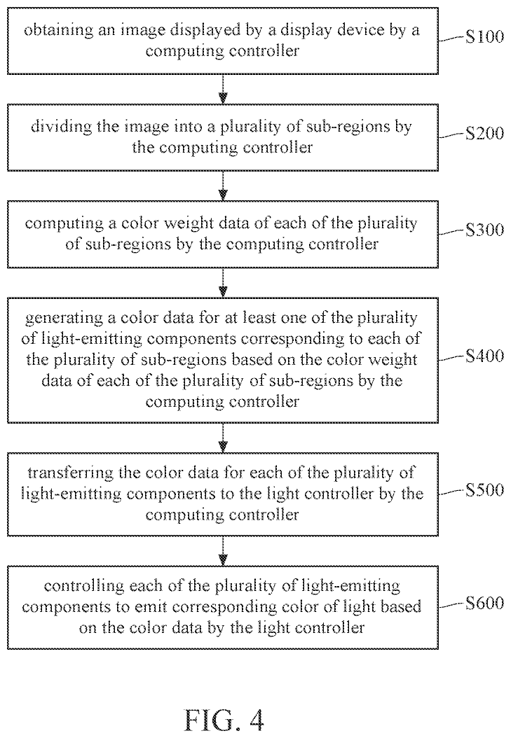

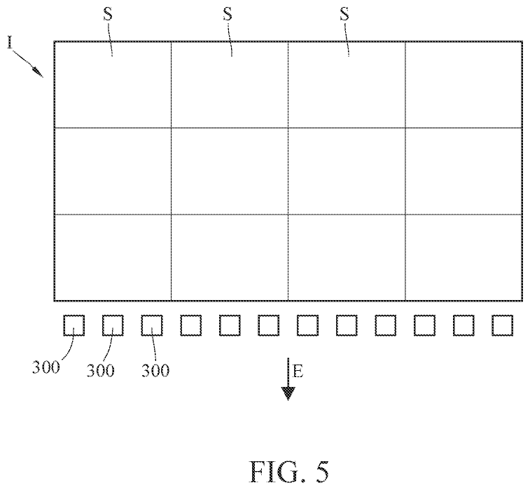

In addition, the light-emitting components 300 according to this disclosure enable an augmented mode of the display device 10. In detail, please refer to FIGS. 1, 4 and 5. FIG. 4 is a flow chart of a method for controlling the display device 10 in FIG. 1. FIG. 5 is a schematic view showing the augmented mode of the display device 10 in FIG. 1.

Hereinafter, a control method of the display device 10 will be described. The display device 10 is switched into the augmented mode through such control method.

In step S100, an image I displayed by the display device 10 is obtained by the computing controller 165. Next, in step S200, the image I is divided into a plurality of sub-regions S by the computing controller 165. Next, in step S300, a color weight data of each sub-region S is computed by the computing controller 165. Next, in step S400, a color data for at least one of the light-emitting components 300 corresponding to each sub-region S is generated based on the color weight data of each sub-region S by the computing controller 165. Note that in this embodiment, each sub-region S corresponds to, for example, three light-emitting components 300. Next, in step S500, the color data for each light-emitting component 300 is transferred to the light controller 350 by the computing controller 165. Next, in step S600, each light-emitting component 300 is controlled to emit corresponding color of light based on the color data via the light controller 350. In the augmented mode, the light-emitting components 300 emit light along an augmented direction E. For example, the light-emitting components 300 emit light downwards from the bottom surface 122 along the augmented direction E. Thus, an augmented image extended from the bottom surface 122 is presented, thereby enhancing the immersion experience of the display device 10.

After the step S600 is completed, the steps S100 to S600 may be repeated for the next frame of the display device 10. In this way, the display device 10 in the augmented mode can accordingly display multiple augmented images via the light-emitting components 300 in a dynamic manner.

According to the display device disclosed by above embodiments, the light emitted by the light-emitting components is partially emitted to the outside along the normal direction of the outer peripheral surface, and partially emitted to the outside along the normal direction of the front surface. Thus, the light-emitting components not only provide state instruction functions by emitting light along the normal direction of the front surface, but also provide a function of displaying augmented images by emitting light along the normal direction of the outer peripheral surface. In this way, the light-emitting components provide various and vivid functions. Moreover, the function of displaying augmented images provides an attractive visual effect and enhance the immersion experience when movies or games are played on the display device.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A control method of display, comprising:
obtaining an image displayed by a display device by a computing controller;
dividing the image into a plurality of sub-regions by the computing controller;
computing a color weight data of each of the plurality of sub-regions by the computing controller;
generating a color data for at least one of a plurality of light-emitting components corresponding to each of the plurality of sub-regions based on the color weight data of each of the plurality of sub-regions by the computing controller;
transferring the color data for each of the plurality of light-emitting components to the light controller by the computing controller; and
controlling each of the plurality of light-emitting components to emit corresponding color of light based on the color data by the light controller.
